(19) United States
(12) Patent Application Publication
(10) Pub. No.: US 2002/0070428 A1
(43) Pub. Date: Jun. 13, 2002

(54) Semiconductor device

(76) Inventors: Hans Bernhoff, Vasteras (SE); Jan Isberg, Vasteras (SE); Per Skytt, Vasteras (SE); Peter Isberg, Vasteras (SE); Mark Irwin, Vasteras (SE); Carina Onneby, Vasteras (SE); Mats Dahlund, Vasteras (SE); Eva Martensson, Vasteras (SE)

Correspondence Address: Pollock, Vande Sande & Amernick, P.O. Box 19088, WASHINGTON, DC, 20036-0088, US

(21) Appl. No.: 09/732,866

(22) Filed: Dec. 11, 2000

(51) Int. Cl. H01L 31/0312; H01L 29/06

(52) U.S. Cl. 257/618; 257/77

(57) ABSTRACT

A semiconductor device comprises means (7) for grading an electric field created in the active part (4) of the device when a high voltage is applied thereacross. Said means comprises a member (7) being of a material having a higher dielectric constant than the material of said active part and applied next to at least a portion of said active part where a high electric field occurs when a high voltage is applied across the device for obtaining a field grading for a condition of changing of said voltage.

### TECHNICAL FIELD OF THE INVENTION AND PRIOR ART

The present invention relates to a semiconductor device comprising means for grading an electric field created in the active part of the device when a high voltage is applied thereacross.

The “active part” includes the part of the device being of a semiconducting material but neither the contacts made thereto nor surrounding insulating material encapsulating the active part. The active part may also be a heterostructure including semiconducting layers of different materials.

The invention is particularly, but not exclusively, directed to semiconductor devices for high power applications.

New materials introduced for especially power semiconductor devices, such as SiC and diamond, have guided the development towards continuously increasing voltages to be held by such semiconductor devices and a decrease of the distance between each device. This means that the electric field also increases resulting in higher electric stresses in and around the material, especially at certain locations where electric field peaks occur. This has resulted in a need of an effective field grading for reducing the electric field where it is highest, i.e. where the equipotential lines have the highest density. There is otherwise an imminent risk that cracks are formed at corners or edges of the active part of the device, where the electric field is the highest, or that discharges between the surrounding insulation and the active part take place there destroying one or both at least partially. The field grading material also protects the device from surface flash-over.

It has for this sake been proposed to provide semiconductor devices having to hold high voltages in a blocking state thereof with means for grading the electric field. This has been done by extending junctions where high voltages occur by gradually reducing the doping concentration in said active part in the lateral direction towards the lateral edge of the device for smearing out the electric field.

It is also known through EP 0 343 797 to apply a member of an electrically conductive material or a semiconducting material outside the active part of a semiconductor device at a lateral edge thereof for locally reducing the electric field through the lower resistivity in said member than in the active part of the device next thereto when a direct voltage is applied to the device.

However, these field grading measures suggested so far are in some cases not enough and will in particular not be sufficient for future semiconductor devices in which even higher electric fields will occur in order to fully utilise the high breakdown voltage of the active part of the device.

### SUMMARY OF THE INVENTION

The object of the present invention is to provide a semiconductor of the type defined in the introduction having means for electric field grading improved in at least some aspects with respect to the devices already known discussed above.

This object is according to the invention obtained by providing such a device in which said means comprises a first member being of a material having a higher dielectric constant than the material of said active part and applied next to at least a portion of said active part where a high electric field occurs when a high voltage is applied across the device for obtaining a field grading for a condition of changing of said voltage.

An arrangement of such a member of a material having a higher dielectric constant than the material of the active part of the device next to the active part will result in a lower electric field in said first member than in the active part as a consequence of a refraction of the field lines at the boundary therebetween for a changing voltage, i.e. a changing electric field. This means that the field lines will be spread apart and the electric field will be reduced at said boundary. Accordingly, this field grading member will take care of electric field stresses resulting from a changing voltage, such as the voltage applied over a semiconductor device connected to an alternating voltage or surge voltages to which a semiconductor device operating at a direct voltage will be subjected to, for instance when starting up an electrical equipment.

Thus, the present invention goes in the opposite direction of the aim of encapsulations of semiconductor components through purely insulating material. It has in certain applications been an attempt to obtain as low dielectric constants as possible for these insulating materials for obtaining a minimal delay of signals in a circuit to which the device belongs. Higher signal propagation speed and signal carrying capacity are also obtained by lowering the dielectric constant of said insulating material. However, this results in an increase of the electric field at the boundary between the active part and the insulation. The invention goes in the other direction while providing the first semiconductor device having means for electric field grading for surge and alternating voltage operation.

According to a preferred embodiment of the invention the dielectric constant of the material of said first member is substantially higher than that of the material of said active part, and it may for instance be more than 1.5, 2 or 3 times higher than the dielectric constant of the material of said active part of the device. Although a small difference in dielectric constant between the material of the active part of the device and said first member results in a field grading, mostly a substantially higher dielectric constant of the material of said first member is necessary for obtaining an optimum field grading. However, it is pointed out that it is not always better to have a dielectric constant being as high as possible, but the field grading property may be almost constant as of a certain value of the dielectric constant, and a further increase thereof could then only result in higher power losses in the material.

According to another preferred embodiment of the invention the dielectric constant of the material of the first member is non-linear and adapted to change with the electric field in the material. Such an non-linear dielectric constant may in certain applications be favourable for obtaining a higher dielectric constant where the field is higher.

According to another preferred embodiment of the invention the device has contacts adapted to connect the device to an alternating voltage during operation thereof, and said first member is surrounded by an insulating material. Such a device will have an advantageous field grading thanks to said first member.

According to another preferred embodiment of the invention said device has contacts adapted to connect the device to a direct voltage for direct voltage operation of the device, and said means comprises a second member being of a material having a lower resistivity than the material of the active part and applied in contact with said active part of the device for obtaining a resistive field grading for direct voltage conditions. This means that such a device intended for direct voltage operation is protected against electric stresses owing to local electric field enhancement through said second member at normal direct voltage operation thereof and through said first member at changes of the voltage level, such as at surge conditions. It is pointed out that it may also be advantageous to combine a first member being of a material having a higher dielectric constant than the material of the active part with a second member being of a material having a lower resistivity than the material of the active part in one and the same device for a combination of a field grading for a condition of changing of said voltage and a resistive field grading for direct voltage conditions.

According to another preferred embodiment of the invention said second member is in contact with two contacts forming a terminal each of the device and establishes a connection therebetween around the active part of the device. This means that a small leakage current may flow from one contact to the other through said second member thus reducing the electric field close to the contacts.

According to another preferred embodiment of the invention the second member is in contact with said active part of the device, which means that it may reduce the electric field at the boundary between the active part and the second member by using lower resistivity of the material of the second member than of the material of the active part next thereto.

According to another preferred embodiment of the invention the device has two contacts arranged on opposite sides of the active part of the device extending laterally beyond the contact, said first member is arranged next to and surrounds the outer edge of the respective contact and the corner formed between the contact and the active part there, and the second member surrounds the first member. This results in an efficient field grading of a semiconductor device intended for direct voltage operation including protection for surge or alternating voltages.

According to another preferred embodiment of the invention said means comprises a plurality of first members arranged at intervals in the lateral direction away from said contact towards a lateral outer edge of said active part next to the active part with said second member reaching the active part between adjacent first members and embedding all the first members. Electric field grading at constant voltage and changing voltage conditions over an extended portion of the active part of the device is obtained. It is pointed out that the different first members may be of different materials for adapting the field grading properties to the need at the respective location. “Different material” also includes the same basic material filled with different particles.

According to other preferred embodiments of the invention said portion of potential high electric field is a corner between a lateral outer edge of the contact applied on the active part and the active part or an outer edge of the active part of the device.

According to another preferred embodiment of the invention the material of said first member is water. Pure water has a very high dielectric constant and is available at a very low cost. Furthermore, the device may be provided with means for circulating the water in contact with the active part of the device for cooling this active part giving the water a double function. However, other liquids than water are also conceivable.

The invention also includes preferable uses of a device according to the invention as defined in the appended use claims as well as a method for providing a semiconductor device with means for grading an electric field created in the active part of the device when a high voltage is applied thereacross or form an insulation around at least a part of the active part of the device according to the appended method claims.

Further advantages as well as advantageous features of the invention will appear from the following description and the other dependent claims.

### BRIEF DESCRIPTION OF THE DRAWINGS

With reference to the appended drawings, below follows a specific description of preferred embodiments of the invention cited as examples.

In the drawings:

FIG. 1 is a schematic view showing the extension of the equipotential lines in a semiconductor device holding a high voltage and surrounded by a purely insulating material having a lower dielectric constant than the material of the active part of the device according to the prior art and achieved by simulations,

FIG. 2 is a view corresponding to FIG. 1 for a semiconductor device according to a preferred embodiment of the invention, in which the active part is surrounded by a material having a higher dielectric constant than the material of the active part of the device for field grading for a condition of changing voltage applied over the device,

FIG. 3 is a cross-section view of a semiconductor device according to a first preferred embodiment of the invention, FIG. 4 is a view of the device according to FIG. 3 in a section along the line IV-IV in FIG. 3,

FIG. 5 is a very schematic view of a device according to a second preferred embodiment of the invention,

FIG. 6 is a schematic view of a device according to a third preferred embodiment of the invention, and

FIG. 7 illustrates very schematically a method for applying an insulating or field grading material onto a semiconductor wafer.

### DETAILED DESCRIPTION OF PREFERRED EMBODIMENTS OF THE INVENTION

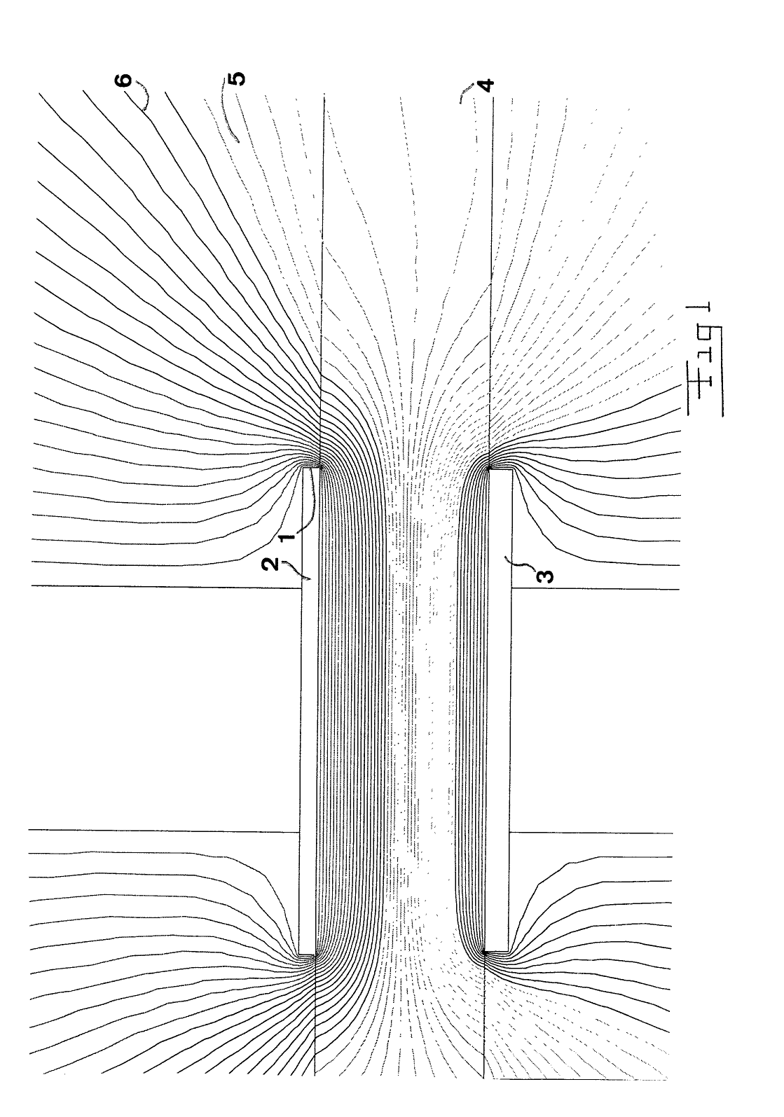

First of all, it is schematically illustrated in FIG. 1 what is occurring at the edge 1 at the respective contact 2, 3 applied on the active part 4 of a semiconductor device when a high voltage in the form of an alternating voltage or the occurrence of a surge is held by the device. In this case the dielectric constant ∈ of the material of the active part is 7, whereas ∈=2 in the insulation 5 surrounding the active part with respect to the ambience. The equipotential lines 6 would already at the same dielectric constant of the two materials have a very high density at the edge 1, and this is due to the lower dielectric constant of the insulation 5 made even worse. This means that the voltage blocking capability of the material of the active part may perhaps not be fully utilised, since when a maximum voltage is applied across the contacts 2, 3 this may result in cracks due to electric stress in the active part at the corner between these contacts and said edge 1. Discharges may also take place partially destroying the insulation and the active part close to the boundary therebetween. Furthermore, a high electric field may cause a surface flash-over.

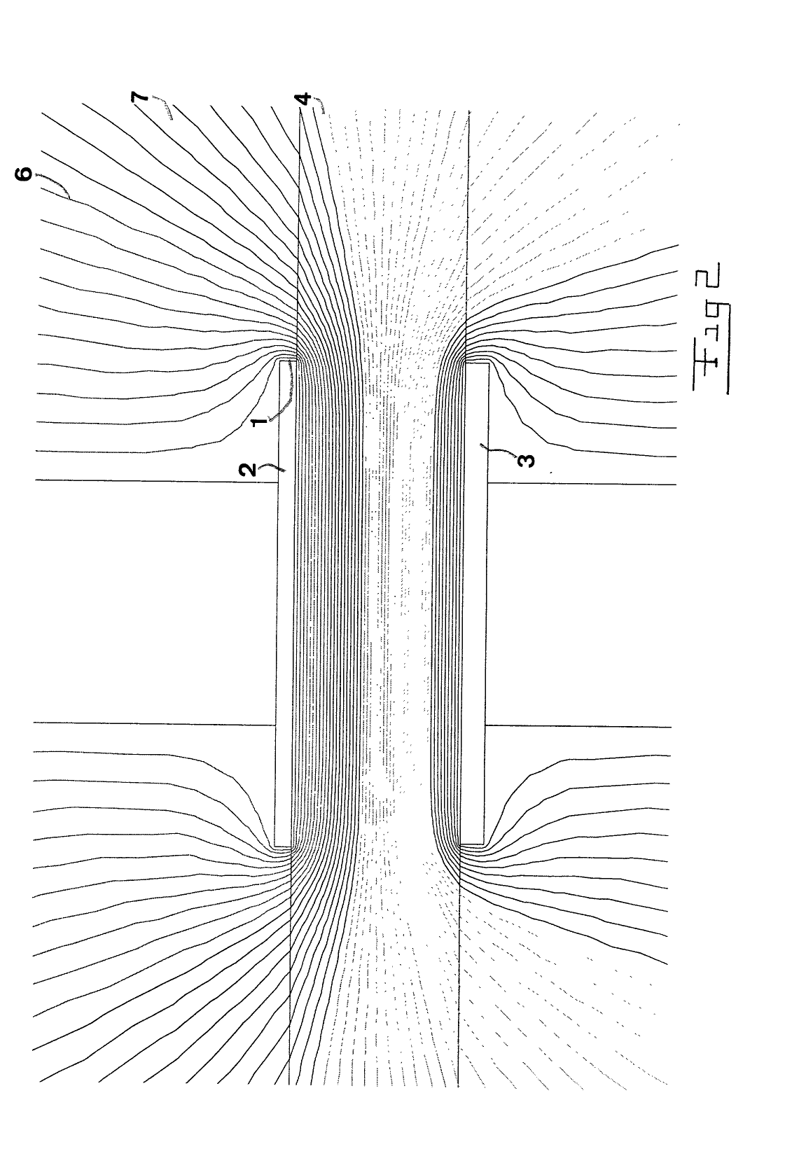

FIG. 2 illustrates how the present invention solves this problem by introducing a first member 7 instead of the insulation 5 being of a material having a higher dielectric constant than the material of the active part 4. In the simulated case shown in FIG. 2 ∈ is 7 for the active part material and ∈ is 12 for the material of the field grading member 7. This results in a spreading of the equipotential lines 6 in the member 7 with respect to the active part as a consequence of the refraction law of the field lines, so that the electric field at the critical edge corner will be reduced and the inherent blocking capability of the active part material may be fully utilised without any risk of any high local electric fields causing damage on the active part or the surrounding material. Accordingly, the electric field close to the outer edge of the contacts is for an alternating voltage and a surge voltage in this way reduced, so that an alternating voltage and surge voltage field grading is obtained.

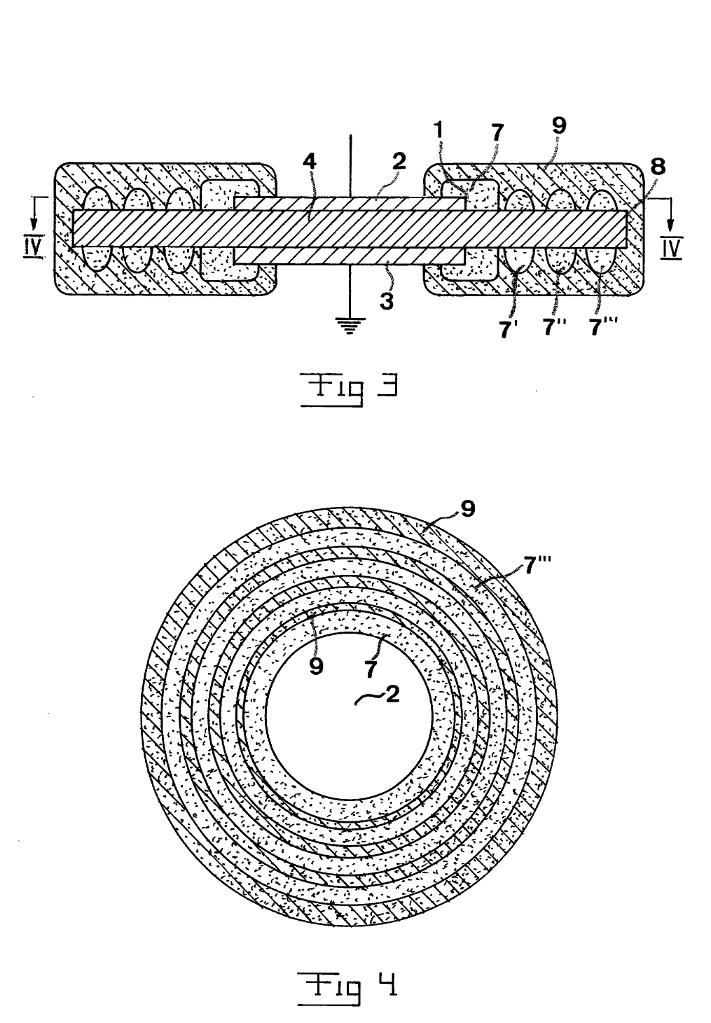

FIG. 3 illustrates a very preferred embodiment of the invention, in which said first member 7 being of a material with a higher dielectric constant than the material of the active part 4 is arranged next to and surrounds the outer edge 1 of the respective contact 2, 3 and the corner formed between the contact and the active part there. Furthermore, additional first members 7′, 7″, 7′″ are arranged at intervals in the lateral direction away from the respective contact towards a lateral outer edge 8 of said active part 4 next to the active part for obtaining an alternating voltage and surge or impulse voltage field grading to utilize the full size of the substrate for field grading.

This device is intended for direct voltage operation and is therefor additionally provided with a second member 9 being of a material having a lower resistivity than the material of the active part and applied in contact with said active part of the device between adjacent first members 7-7′″ and embedding all the first members for obtaining a resistive grading for direct voltage conditions. Furthermore, the second member 9 is in contact with the two contacts 2, 3 while establishing a connection therebetween around the active part of the device. The second member 9 results in a field reduction during direct voltage operation thanks to a lower resistivity of the material thereof than of the material of the active part of the device. In practice, this means that a leakage current may in the blocking state of the device flow from one contact to the other through this second member, but this current should be kept at a low level for not degrading the blocking capability of the device.

The active part 4 of the device is preferably of a wide band gap material, i.e. a material having an energy gap between the valence band and the conduction band exceeding 1.5 eV, such as SiC or diamond. This means that the active part 4 may be made very thin and still be able to hold a high voltage in the blocking state thereof resulting in high electric fields. Thanks to the arrangement of the first members and the second member an efficient field grading for the steady state direct voltage case and also for surge voltages suddenly occurring may be obtained. It may be mentioned that ∈ is 5.7 for diamond, and it has for the first member to exceed this value.

It is shown in FIG. 4 how the different first members are arranged as concentric rings, and it is pointed out that the different rings may be made of materials having different field grading properties, i.e. different dielectric constants and resistivities. This material may for instance be any gel, composite, varnish, polymer or rubber based material, such as epoxy, silicone gel, silicone rubber or EPDM rubber. Said material can be filled with particles increasing the dielectric constant thereof, such as particles of SiC, BaTiO₃, TiO₂, Al₂O₃, MgO, ZnO . . . The rings 7-7′″ could also be thin films (such as BaTiO₃ or TiO₂) with desired properties.

FIG. 5 illustrates a semiconductor device according to another preferred embodiment of the invention, which differs from that according to FIG. 3 by the fact that said first member 7 of a material having a higher dielectric constant than the active part 4 of the device is water, and the entire active part with contacts 2, 3 are fully immersed in a closed vessel 10 filled with water. It is shown how one 2 of the contacts is provided with apertures for obtaining control of the active part of the device through light. Water has a very high dielectric constant, in the order of 80, and has in a pure state a high dielectric strength (200 kV/cm). The water may be filled by nanoparticles (particles having a size of 1-100 nm) for increasing the dielectric constant and/or the dielectric strength. It may be chosen to add such particles with a tendency to absorb ions for taking care of the risk of ionisation of pure water. The pure water could also serve as a resistive field grading due to its relative high conductivity.

In addition to field grading function the water can also be utilised to cool the active part 4 of the device, and means 11 is provided for circulating the water in contact with the active part of the device for this sake. A deionizer 11a is arranged to purify the water before recirculation.

Another advantage of using water or any other liquid as field grading material is that there will be no mechanical pressure on the active part of the device and no material stresses caused upon thermal expansion as a consequence of different coefficients of thermal expansion. The use of water may also be combined with other field grading members, such as members for additional resistive field grading, e.g. applied on the active part.

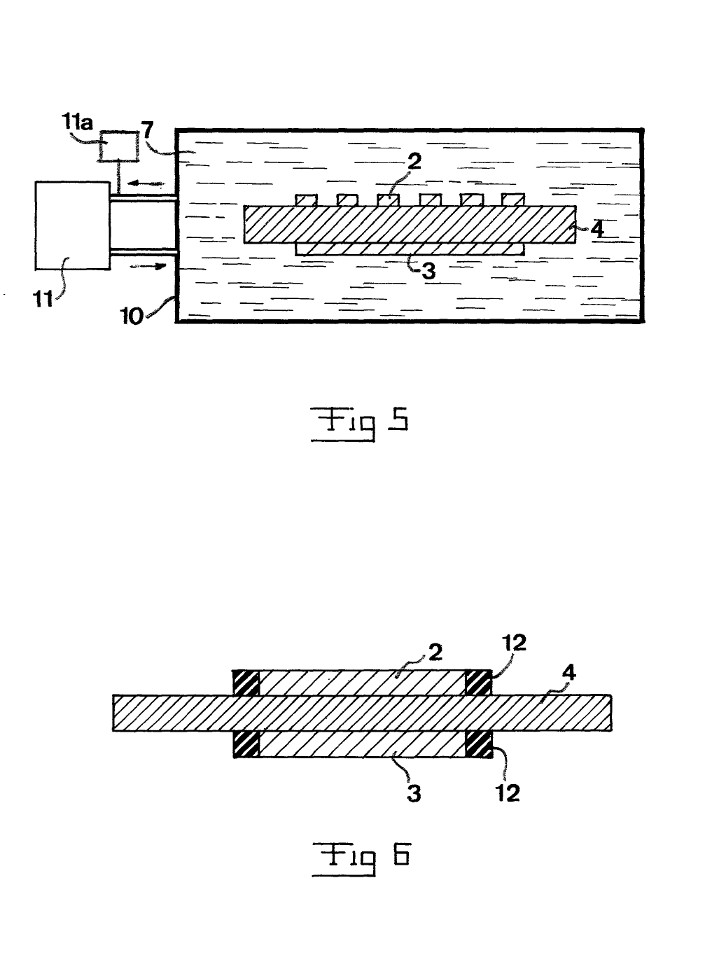

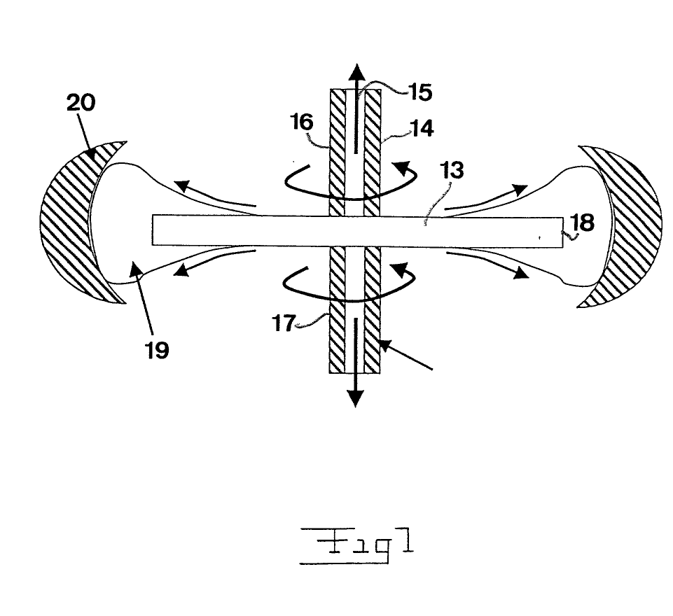

A device according to a further preferred embodiment of the invention is schematically illustrated in FIG. 6. This device has a first member in the form of an O-ring 12 of an elastic material adapted to be applied on the active part of the device while being stretched for storing potential energy therein for obtaining a snug fit to said active part. More exactly, the O-ring is applied around each contact 2, 3 of the device forming a terminal thereof for bearing laterally thereagainst and on portions of the active part of the device next to the contact. This O-ring will preferably be of a material having a higher dielectric constant than the material of the active part 4 and has substantially the same influence upon the electric field as the member 7 in the embodiment according to FIG. 3. The O-ring has in a resting (unstretched) state thereof a cross-section being substantially complementary to the cross-section of the transition between said contact and the active part of the device next thereto, which in the present case means a substantially square cross-section, i.e. the shape of the O-ring fits to the shape of the contact and active part at said transition. In other cases the contact may be shaped so that an O-ring having a circular cross-section will suit, but it will also be possible to fill out any gap between the O-ring and the regions of the contact and the active part at the transition thereof with any suitable material. The O-ring may be provided with different layers of different materials or of the same material with different additives, so that it may for instance also have a part with a lower resistivity than the resistivity of the active part of the device for field grading at direct voltage operation of the device.

An important advantage of using such an O-ring is the simplification of the assembly process made possible therethrough. Insulations have until now been applied in a much more complicated way, such as by applying silicon gel in a vacuum furnace requiring establishing of a vacuum, heating the material and so on in a number of process steps, which is to be compared with just stretching the O-ring and put it in place around the contact. Accordingly, the application of the field grading member does not add any processing step, but it is instead a part of the assembling of the component package.

The O-ring may also be replaced by a seal with no elastic properties. This embodiment is particularly advantageous when a liquid metal is used as said contact 2 and/or 3, since the O-ring will then also ensure the position of the contact and determine the shape of the contact edge.

The devices may be any type of high voltage devices, which may be adapted to hold a voltage of more than 1 kV, perhaps more than 5 kV or even more than 10 kV in the blocking state thereof. We may here mention rectifying diodes, thyristors, IGBTs and MISFETs. Such a device may be used in for instance current valves of converters for converting direct voltage into alternating voltage or direct voltage and conversely, such as in HVDC stations (High Voltage Direct Current). Other preferable uses are in tap changers and in current limiters, preferably as switches.

FIG. 7 illustrates a method in the form of a so called spin-on process for providing a semiconductor device with means for grading an electric field created in the active part of the device when a high voltage is applied thereacross or forming an insulation around at least a part of the active part of the device. It is shown how a piece 13, here of a wide band gap semiconductor material, adapted to form the active part of the device is held by a vacuum chuck 14 for not degrading the surface of the piece 13. It is shown by arrows 15 how a negative pressure is formed inside the chuck members 16, 17. However, it would be possible to supply material forming said means through one of these members 16, 17 and create a negative air pressure in only one of them. The material to be applied on the active part 13 is in any case supplied substantially centrally to the active part, which is rotated, so that the material migrates regularly towards the lateral edges of the active part. At a lateral distance to the lateral outer edge 18 of the piece 13 a constraining mould 20 is provided for preventing the material from moving further laterally than to this resulting in a shaping of the material 19. It is pointed out that the material supplied in this way has not necessarily to be field grading, but it may also be only insulating. It is possible to adjust the rotation speed and the supply rate of the material for influencing the shape of the field grading or insulating member formed in this way.

Corresponding materials have until now been applied by dipping the entire piece 13 into a bath of for instance silicon gel, but this may be delicate if the piece 13 is of a fragile material, since it is necessary to hold the piece in some way. However, this is not needed here, and it will also be possible to better distribute particles that may be added to the material 19 through the rotation than if it would be poured onto the piece 13 or a material applied thereon. It is also easier to obtain a determined shape of the material applied, since a layer being thin at the centre and thick at the edges may be obtained, which is not possible when pouring the material on the piece 13. This method is especially suited for applying field grading and insulating materials to fragile substrates (active parts), since it minimizes stresses applied to the substrate during processing. This is particularly important for brittle diamond substrates.

The invention is of course not in any way restricted to the preferred embodiments thereof described above, but many possibilities to modifications thereof would be apparent to a man with ordinary skill in the art without departing from the basic idea of the invention as defined in the appended claims.

The active part of the devices as well as the field grading members may of course have totally different shapes than those shown in the figures. It is noticed that the active part of the devices may and will almost always contain intentional dopants as well as inevitable impurities.

1. A semiconductor device comprising means for grading an electric field created in the active part of the device when a high voltage is applied thereacross, characterized in that said means comprises a first member (7) being of a material having a higher dielectric constant than the material of said active part (4) and applied next to at least a portion of said active part where a high electric field occurs when a high voltage is applied across the device for obtaining a field grading for a condition of changing of said voltage.

2. A device according to claim 1, characterized in that the dielectric constant of the material of said first member (7) is substantially higher than that of the material of said active part (4).

3. A device according to claim 2, characterized in that the dielectric constant of the material of said member is more than 1.5, 2 or 3 times higher than the dielectric constant of the material of said active part of the device.

4. A device according to claim 1, characterized in that the dielectric constant of the material of the first member is nonlinear and adapted to change with the dielectric field in the material.

5. A device according to any of the preceding claims, said device having contacts (2, 3) adapted to connect the device to an alternating voltage during operation thereof, characterized in that said first member (7) is surrounded by an insulating material.

6. A device according to any of claims 1-4, said device having contacts (2, 3) adapted to connect the device to a direct voltage for direct voltage operation of the device, characterized in that said means comprises a second member (9) being of a material having a lower resistivity than the material of the active part and applied in contact with said active part (4) of the device for obtaining a resistive field grading for direct voltage conditions.

7. A device according to claim 6, characterized in that the resistivity of the material of said second member (9) is substantially lower than that of the material of said active part.

8. A device according to claim 6 or 7, characterized in that said second member (9) is in contact with two contacts (2, 3) forming a terminal each of the device and establishes a connection therebetween around the active part (4) of the device.

9. A device according to any of claims 6-8, characterized in that the second member (9) is in contact with said active part (4) of the device.

10. A device according to any of claims 6-9 having two contacts (2, 3) arranged on opposite sides of an active part (4) of the device extending laterally beyond the contacts, characterized in that said first member (7) is arranged next to and surrounds the outer edge of the respective contact and the corner formed between the contact and the active part there, and that the second member (9) surrounds the first member.

11. A device according to claim 10, characterized in that said means comprises a plurality of first members (7, 7′, 7″, 7′″) arranged at intervals in the lateral direction away from said contact towards a lateral outer edge (8) of said active part next to the active part with said second member (9) reaching the active part between adjacent first members and embedding all the first members.

12. A device according to claim 11, characterized in that said first members (7, 7′, 7″, 7′″) are arranged as substantially concentric rings.

13. A device according to claim 11 or 12, characterized in that at least two first members are of materials having different field grading properties.

14. A device according to any of the preceding claims, characterized in that said portion of potential high electric field is a corner between a lateral outer edge (1) of a contact (2, 3) applied on the active part and the active part (4).

15. A device according to any of the preceding claims, characterized in that said portion of potential high electric field is an outer edge (8) of the active part (4) of the device.

16. A device according to any of the preceding claims, characterized in that the material of said first member (7) is a rubber filled with particles influencing the dielectric constant thereof.

17. A device according to claim 16, characterized in that the material of said first member is an EPDM-rubber filled with BaTiO₃-,TiO₂-,Al₂O₃-,MgO-,ZnO-or SiC-particles.

18. A device according to any of claims 1-15, characterized in that the material of said first member is a liquid (7).

19. A device according to claim 18, characterized in that the material of said first member is water.

20. A device according to claim 18 or 19, characterized in that the entire active part of the device is surrounded by said liquid.

21. A device according to claim 20, characterized in that it comprises a vessel (10) filled with said liquid (7) in which the rest of the device is fully immersed.

22. A device according to any of claims 18-21, characterized in that it comprises means (11) for circulating the liquid in contact with the active part of the device for cooling this active part.

23. A device according to claim 22, characterized in that at least one contact of the device forming a terminal thereof is provided with channels and said circulating means (10) is adapted to bring said liquid to circulate in said channels for cooling the active part (4) of the device.

24. A device according to any of claims 18-23, characterized in that the liquid is filled with particles changing the dielectric constant of the liquid.

25. A device according to claim 24, characterized in that said particles in the liquid are adapted to increase the dielectric constant and/or the dielectric strength of the liquid.

26. A device according to claim 24 or 25, characterized in that said particles have a size in the range of 1-100 nm.

27. A device according to any of claims 1-17, characterized in that said first member being formed by an O-ring (12) of an elastic material adapted to be applied on the active part (4) of the device while being stretched for storing potential energy therein for obtaining a snug fit to said active part when applied next thereto.

28. A device according to claim 27, characterized in that said O-ring (12) is applied around each contact (2, 3) of the device forming a terminal thereof for bearing laterally thereagainst and on portions of the active part of the device next to the contact.

29. A device according to claim 28, characterized in that said O-ring (12) has in a resting state thereof a cross-section being substantially complementary to the cross-section of the transition between said contact and the active part of the device next thereto.

30. A device according to any of claims 27-29, characterized in that said O-ring (12) is formed by a plurality of layers having different field grading properties, such as dielectric constant for field grading for conditions of changing voltages and resistivity for field grading at constant voltages.

31. A device according to any of the preceding claims, characterized in that said active part (4) of the device is made of a material having a wide energy gap, i.e. exceeding 1.5 eV, between the valence band and the conduction band thereof.

32. A device according to claim 31, characterized in that said material is SiC.

33. A device according to claim 31, characterized in that said material is diamond.

34. A device according to any of the preceding claims, characterized in that said active part (4) of the device is designed to be able to block a voltage of at least 1 kV.

35. A device according to claim 34, characterized in that said active part (4) of the device is designed to be able to block a voltage of at least 5 kV.

36. A device according to claim 34, characterized in that said active part (4) of the device is designed to be able to block a voltage of at least 10 kV.

37. A device according to any of the preceding claims, characterized in that it is a diode, a thyristor, an IGBT or a MISFET.

38. A method for providing a semiconductor device with means for grading an electric field created in the active part of the device when a high voltage is applied thereacross or form an insulation around at least a part of the active part of the device, characterized in that a piece (13) adapted to form the active part of the device is rotated while centrally supplying a field grading or insulating material thereto, so that this material is influenced towards the lateral edges (18) thereof.

39. A method according to claim 38, characterized in that a constraining mould (20) is arranged laterally around said piece (13) at a lateral distance thereto for preventing said material from moving further laterally and by that laterally shaping the field grading or insulating means.

40. A method according to claim 38 or 39, characterized in that the rotation speed of said piece is controlled for controlling the distribution of said material (19) in the lateral direction of said piece.

41. A use of a device according to any of claims 1-37 in equipment for handling high powers and/or high voltages and/or high currents.

42. A use of a device according to any of claims 1-37 in a converter for converting a direct voltage into an alternating voltage or a direct voltage or conversely.

43. A use of a device according to any of claims 1-37 as a switch for protecting equipment for high power applications.

44. A use of a device according to any of claims 1-37 in a current limiter.

45. A use of a device according to any of claims 1-37 in a tap changer.
